(19) United States
(12) Patent Application Publication
(10) Pub. No.: US 2026/0215201 A1
(43) Pub. Date: Jul. 23, 2026

(54) APPARATUS WITH EXHAUST BAFFLE

(71) Applicant: Taiwan Semiconductor Manufacturing Company Limited, Hsin-Chu (TW)

(72) Inventors: Kai-Wen CHENG, Yunlin County (TW); Wei-Da CHEN, Hsinchu County (TW); Yen-Hsiang LIANG, New Taipei City (TW); Yi-Hao LO, Taoyuan City (TW)

(21) Appl. No.: 19/028,519

(22) Filed: Jan. 17, 2025

(51) Int. Cl. H01L 21/67; H01L 21/687

(52) U.S. Cl. CPC H10P 72/0421; H10P 72/7614

(57) ABSTRACT

An apparatus is provided. The apparatus includes one or more chamber walls defining a processing chamber. The apparatus includes a gas inlet port defined by one or more inlet port walls configured to conduct a process gas into the processing chamber. The apparatus includes an exhaust port defined by one or more exhaust port walls through which the process gas is removed from the processing chamber. The apparatus includes an exhaust baffle having an oval-shaped opening defined by one or more exhaust baffle walls. A flow path, along which the process gas flows as the process gas is removed from the processing chamber, passes through the oval-shaped opening.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a block diagram schematically depicting an apparatus, in accordance with some embodiments.

FIG. 1B illustrates a perspective view of an apparatus, in accordance with some embodiments.

FIG. 2A illustrates a top view of a first exhaust baffle, an exhaust port, and a first pedestal base, in accordance with some embodiments.

FIG. 2B illustrates a top view of a first exhaust baffle, in accordance with some embodiments.

FIG. 2C illustrates a top view of a first exhaust baffle, in accordance with some embodiments.

FIG. 3 illustrates a perspective view of an apparatus, in accordance with some embodiments.

FIG. 4A illustrates a top view of a first exhaust baffle, a first pedestal base, a second exhaust baffle, a second pedestal base, and an exhaust port, in accordance with some embodiments.

FIG. 4B illustrates a top view of a second exhaust baffle, in accordance with some embodiments.

FIG. 4C illustrates a top view of a second exhaust baffle, in accordance with some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

An apparatus is used to perform a semiconductor fabrication process on a semiconductor wafer in which the semiconductor wafer is exposed to a process gas. The apparatus includes a wafer support structure configured to support the semiconductor wafer in a processing chamber defined by one or more chamber walls. The apparatus includes a gas inlet port to conduct a process gas into the processing chamber. The apparatus includes an exhaust port defined by one or more exhaust port walls through which the process gas is removed from the processing chamber. The apparatus includes an exhaust baffle having an oval-shaped opening (e.g., at least one of egg-shaped opening, ellipse-shaped opening, etc.) defined by one or more exhaust baffle walls. A flow path, along which the process gas flows as the process gas is removed from the processing chamber, passes through the oval-shaped opening. The exhaust baffle having the oval-shaped opening provides for increased uniformity of distribution of the process gas across the semiconductor wafer in comparison with implementations that do not have exhaust baffles or have exhaust baffles that do not include oval-shaped openings. In some embodiments, the semiconductor fabrication process comprises an etching process. In some embodiments, at least one of the exhaust baffle having the oval-shaped opening or orienting the oval-shaped opening in accordance with one, some or all of the techniques herein provides for increased uniformity of etch rates (e.g., about 4.6% increase of etch rate uniformity) across the semiconductor wafer, such as increased uniformity of etch rates across an edge region (and/or a central region) of the semiconductor wafer. In some embodiments, the increased etch rate uniformity provides for at least one of improved quality of the semiconductor wafer, improved operation (e.g., reliability, predictability, longevity, tolerance(s), etc.) of a semiconductor device formed from the semiconductor wafer, etc. In some embodiments, the semiconductor device comprises one or more transistors having gate-all-around architecture.

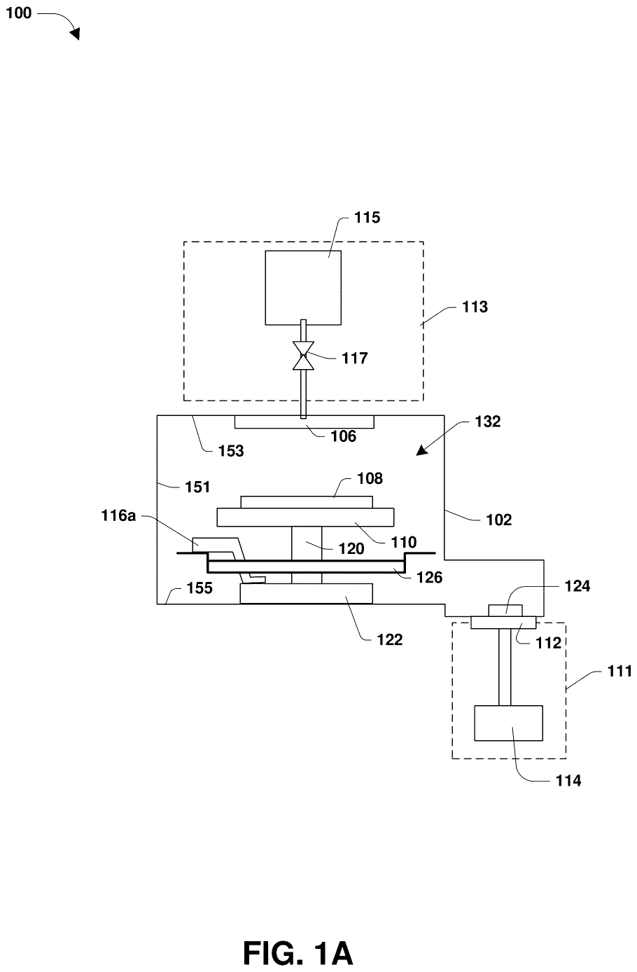

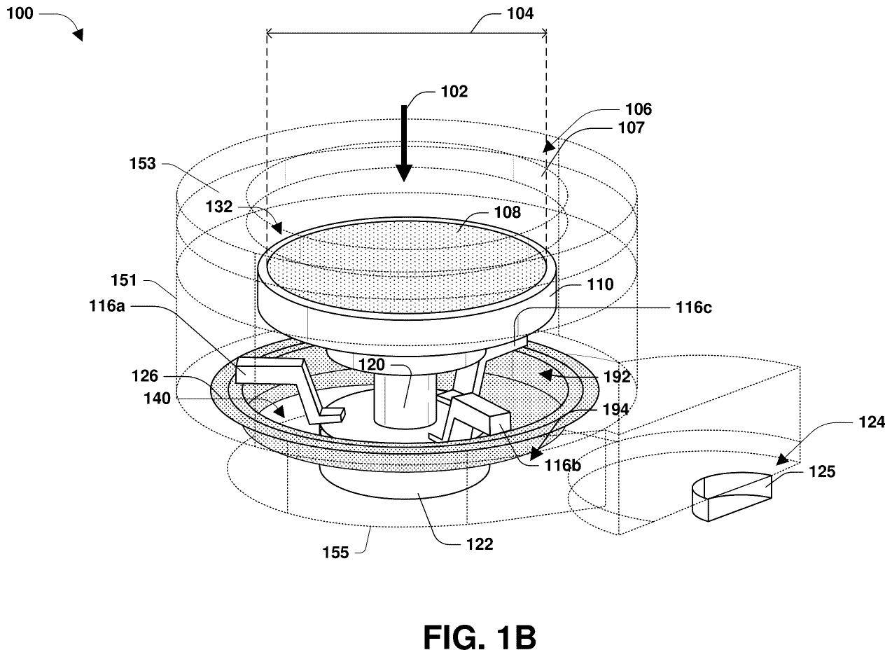

FIGS. 1A-1B illustrate an apparatus 100, in accordance with some embodiments. FIG. 1A illustrates a block diagram schematically depicting the apparatus 100, in accordance with some embodiments. In some embodiments, the apparatus 100 comprises at least one of a first ceiling 153, a first floor 155, or one or more first chamber walls, such as a first peripheral wall 151, to define a first processing chamber 132. In some embodiments, at least one of (i) the first floor 155 is annular, (ii) the first ceiling 153 is annular, or (iii) the first peripheral wall 151 is cylindrical such that at least some of the first processing chamber 132 is a cylindrical volume.

In some embodiments, the apparatus 100 comprises a semiconductor processing station for processing one or more semiconductor wafers. In some embodiments, the apparatus 100 is configured to perform a first semiconductor fabrication process on a semiconductor wafer. In some embodiments, the apparatus 100 comprises a first wafer support structure 110 configured to support a first semiconductor wafer 108 in the first processing chamber 132. A diameter 104 (shown in FIG. 1B) of the first semiconductor wafer 108 is at least one of (i) between about 10 millimeters to about 3,000 millimeters, (ii) between about 100 millimeters to about 500 millimeters, or (iii) between about 250 millimeters to about 350 millimeters. Other values of the diameter 104 are within the scope of the present disclosure. In some embodiments, the first semiconductor wafer 108 is subjected to the first semiconductor fabrication process while the first semiconductor wafer 108 is supported by the first wafer support structure 110. In some embodiments, the first wafer support structure 110 comprises at least one of a pedestal, a platform, a chuck, etc. that at least one of (i) supports the first semiconductor wafer 108 via electrostatic clamping (ESC), (ii) supports the first semiconductor wafer 108 via mechanical clamping, or (iii) supports the first semiconductor wafer 108 using one or more other suitable techniques. In some embodiments, the first semiconductor wafer 108 comprises at least one of a substrate, a photomask, a semiconductor device, a die, etc.

In some embodiments, the first semiconductor fabrication process comprises exposing the first semiconductor wafer 108, such as a surface of the first semiconductor wafer 108, to a first process gas. The first semiconductor fabrication process comprises an etching process. The semiconductor processing station comprises etching equipment, such as at least one of plasma etching equipment, wet etching equipment, dry etching equipment, reactive-ion etching (RIE) equipment, atomic layer etching (ALE) equipment, or buffered oxide etching equipment. The first process gas comprises a first etching gas comprising at least one of methane (CH4), hydrogen (H2), helium (He), plasma, one or more etching chemicals, or one or more other suitable gases and/or chemicals. Other types of semiconductor fabrication processes, semiconductor processing stations and/or process gases are within the scope of the present disclosure. In some embodiments, the apparatus 100 comprises a first pedestal base 122 configured to support the first wafer support structure 110. In some embodiments, the first pedestal base 122 provides foundational support to the first wafer support structure 110. In some embodiments, a first object 120, such as a cylinder, extends between the first pedestal base 122 and the first wafer support structure 110. In some embodiments, at least one of a first side (e.g., bottom side) of the first object 120 is attached to the first pedestal base 122 or a second side (e.g., top side) is attached to the first wafer support structure 110. In some embodiments, the first semiconductor wafer 108 comprises a gate-all-around transistor architecture. In some embodiments, the first semiconductor fabrication process comprises a stage (e.g., etching stage) of fabrication of a semiconductor device comprising one or more transistors having gate-all-around architecture.

In some embodiments, the apparatus 100 comprises a first gas inlet port 106. In some embodiments, the first gas inlet port 106 is defined by one or more first inlet port walls of the apparatus 100, such as a first gas inlet port wall 107 (shown in FIG. 1B). In some embodiments, the first gas inlet port 106 is configured to conduct the first process gas into the first processing chamber 132. In some embodiments, the apparatus 100 comprises a first showerhead (e.g., a mars showerhead) that introduces the first process gas into the first processing chamber 132 via the first gas inlet port 106 defined by the first showerhead and one or more other apertures (not shown) defined by the first showerhead (e.g., the first gas inlet port 106 corresponds to an aperture of a plurality of apertures defined by the first showerhead to introduce the first process gas into the first processing chamber 132).

In some embodiments, the first process gas is conducted from a first gas source 113 through the first gas inlet port 106 into the first processing chamber 132. In some embodiments, the first process gas is stored in a first cylinder 115 of the first gas source 113. In some embodiments, the first gas source 113 is fluidly coupled to the first gas inlet port 106 and/or the first processing chamber 132 through a first control valve 117. In some embodiments, the first control valve 117 regulates the flow of the first process gas from the first cylinder 115 into the first processing chamber 132. In some embodiments, the first gas inlet port 106 conducts at least some of the first process gas in a direction 102 (e.g., downwards direction) into the first processing chamber 132.

In some embodiments, the apparatus 100 comprises an exhaust port 124. In some embodiments, the exhaust port 124 is defined by one or more exhaust port walls of the apparatus 100, such as exhaust port wall 125 (shown in FIG. 1B). In some embodiments, the first process gas is removed from the first processing chamber 132 through the exhaust port 124.

In some embodiments, the apparatus 100 comprises a vacuum source 111 that is fluidly coupled to the first processing chamber 132 through the exhaust port 124 to expose the first processing chamber 132 to a vacuum (e.g., partial vacuum) established by the vacuum source 111. In some embodiments, the vacuum (e.g., the partial vacuum) is at a lower pressure than a pressure within the first processing chamber 132 such that at least a portion of the first process gas flows along a flow path from the first processing chamber 132 to the vacuum source 111 through the exhaust port 124. In some embodiments, the vacuum source 111 comprises a vacuum pump 114, such as a turbo pump or any other suitable pump that is operable to establish a pressure that is less than the pressure within the first processing chamber 132. In some embodiments, the vacuum source 111 comprises an adaptive pressure controller 112 that regulates a pressure to which the first processing chamber 132 is exposed via the vacuum pump 114.

In some embodiments, the apparatus 100 comprises a first exhaust baffle 126. In some embodiments, the first exhaust baffle 126 is between the first pedestal base 122 and the first wafer support structure 110. In some embodiments, the first exhaust baffle 126 has a first oval-shaped opening 140 (shown in FIG. 1B). In some embodiments, the first object 120 extends through the first oval-shaped opening 140 between the first pedestal base 122 and the first wafer support structure 110. In some embodiments, a first flow path, along which the first process gas flows as the first process gas is removed from the first processing chamber 132, passes through the first oval-shaped opening 140 of the first exhaust baffle 126. In some embodiments, the first exhaust baffle 126 is at least partially sealed against the first peripheral wall 151 (and/or other wall defining the first processing chamber 132) such that most or all of gas that flows from a first part of the first processing chamber 132 over the first exhaust baffle 126 to a second part of the first processing chamber 132 under the first exhaust baffle 126 is conducted through the first oval-shaped opening 140 (e.g., none of the gas or less than a threshold amount of the gas is conducted from over the first exhaust baffle 126 to under the first exhaust baffle 126 through an unsealed gap between an edge of the first exhaust baffle 126 and the first peripheral wall 151).

In some embodiments, the first exhaust baffle 126 having the first oval-shaped opening 140 provides for increased uniformity of distribution of the first process gas across the first semiconductor wafer 108, such as where different portions of the first semiconductor wafer 108 are exposed to similar and/or more uniform amounts of the first process gas during the first semiconductor fabrication process. In some embodiments, the increased uniformity associated with the first process gas (e.g., the etching gas) provides improved processing uniformity (e.g., etching uniformity of etching rates) of the first semiconductor fabrication process (e.g., etching process). In some embodiments, a first flow rate of a first portion of the first process gas over a first portion of the first semiconductor wafer 108 is equal or about equal to a second flow rate of a second portion of the first process gas over a second portion of the first semiconductor wafer 108 due to the first exhaust baffle 126 having the first oval-shaped opening 140. In some embodiments, the first portion of the first semiconductor wafer 108 is proximal an edge of the first semiconductor wafer 108 and distal a center of the first semiconductor wafer 108. In some embodiments, the second portion of the first semiconductor wafer 108 is proximal the center of the first semiconductor wafer 108 and distal the edge of the first semiconductor wafer 108. In some embodiments, a difference between the first flow rate and the second flow rate is reduced due to the first exhaust baffle 126 having the first oval-shaped opening 140. In some embodiments, a first etch rate of the first portion of the first semiconductor wafer 108 is equal or about equal to a second etch rate of the second portion of the first semiconductor wafer 108, such as due, at least in part, to the first exhaust baffle 126 having the first oval-shaped opening 140. In some embodiments, a difference between the first etch rate and the second etch rate is reduced due, at least in part, to the first exhaust baffle 126 having the first oval-shaped opening 140.

In some embodiments, the exhaust port 124 is laterally offset from at least one of the first semiconductor wafer 108, the first wafer support structure 110, the first exhaust baffle 126, the first object 120, or the first pedestal base 122. In some embodiments, the first gas inlet port 106 overlies at least one of the first semiconductor wafer 108, the first wafer support structure 110, the first exhaust baffle 126, the first object 120, or the first pedestal base 122. In some embodiments, the first semiconductor wafer 108 overlies at least one of the first wafer support structure 110, the first exhaust baffle 126, the first object 120, or the first pedestal base 122. In some embodiments, the first wafer support structure 110 overlies at least one of the first exhaust baffle 126, the first object 120, or the first pedestal base 122. In some embodiments, at least one of the first object 120 or the first exhaust baffle 126 overlies the first pedestal base 122. In some embodiments, the first oval-shaped opening 140 defined by the first exhaust baffle 126 overlies the first pedestal base 122.

FIG. 1B illustrates a perspective view of the apparatus 100, in accordance with some embodiments. For clarity, some of the apparatus 100 (e.g., the first ceiling 153, the first floor 155, one or more chamber walls, one or more other parts of a body of the apparatus 100, etc.) are depicted transparently with dotted-line boundaries in FIG. 1B. In some embodiments, the apparatus 100 comprises a first set of pin holders (e.g., a set of one or more pin holders). Although FIG. 1B shows three pin holders of the first set of pin holders, other numbers of pin holders of the first set of pin holders other than three are within the scope of the present disclosure. In some embodiments, the first set of pin holders comprises at least one of a first pin holder 116a, a second pin holder 116b, a third pin holder 116c, or one or more other pin holders that provide structural support, integrity, etc. to one or more features, elements, etc. to which one or more of the pin holders are respectively attached.

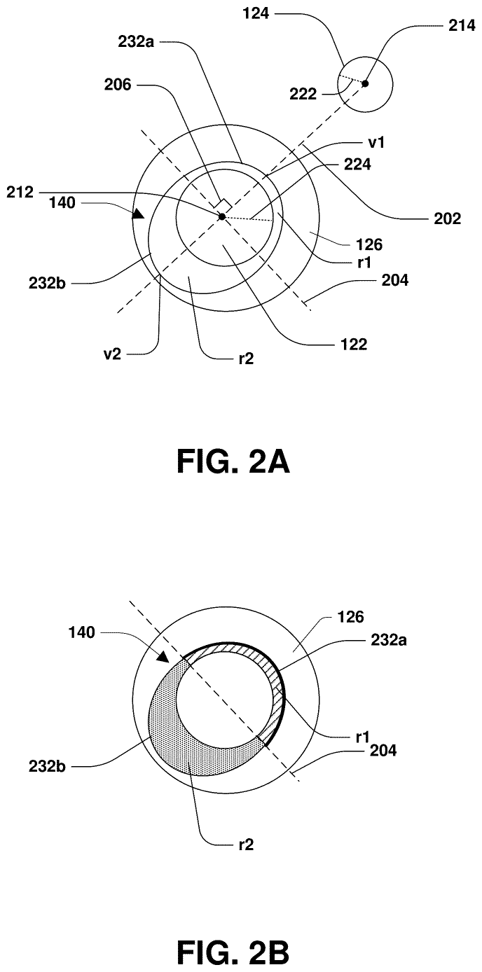

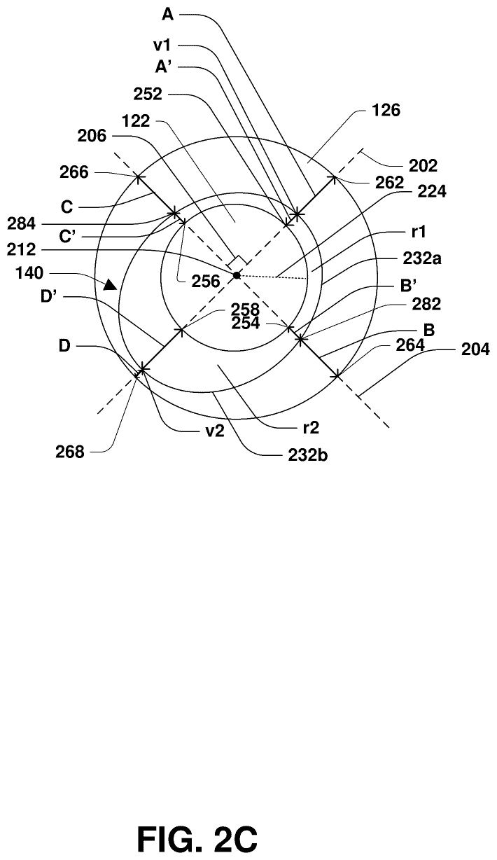

In some embodiments, an orientation of the first oval-shaped opening 140 defined by the first exhaust baffle 126 is configured based upon an orientation of the exhaust port 124 relative to the first exhaust baffle 126 to provide for increased uniformity of distribution of the first process gas across the first semiconductor wafer 108. In some embodiments, the first oval-shaped opening 140 is oriented using one or more of the techniques provided herein with respect to FIGS. 2A-2C.

FIG. 2A illustrates a top view of the first exhaust baffle 126 and the first oval-shaped opening 140 of the first exhaust baffle 126 relative to the exhaust port 124 and the first pedestal base 122, in accordance with some embodiments. In some embodiments, the first oval-shaped opening 140 has a first vertex v1 and a second vertex v2. The first vertex v1 is associated with a first curvature. The second vertex v2 is associated with a second curvature. In some embodiments, the first curvature is different than the second curvature such that the first oval-shaped opening 140 has a more rounded and/bulbous end and a more narrow and/or tapered end. In some embodiments, the second curvature is greater than the first curvature (e.g., the first vertex v1 corresponds to the more rounded and/bulbous end of the first oval-shaped opening 140 and the second vertex v2 corresponds to the more narrow and/or tapered end of the first oval-shaped opening 140). Although FIG. 2A illustrates an embodiment in which the first curvature is different than the second curvature, embodiments are contemplated in which at least one of (i) the first curvature is about equal to the second curvature, (ii) the first oval-shaped opening 140 has an elliptical shape, or (iii) the first oval-shaped opening 140 is symmetrical and/or substantially symmetrical about two axes (e.g., major axis and minor axis).

In some embodiments, a first major axis 202 of the first oval-shaped opening 140 intersects with the first vertex v1 and the second vertex v2. In some embodiments, the first oval-shaped opening 140 is oriented such that the first major axis 202 of the first oval-shaped opening 140 intersects at least one of a point on the exhaust port 124, a center point 214 associated with the exhaust port 124 or a point (e.g., a point on the exhaust port 124) that is within a first threshold distance of the center point 214 associated with the exhaust port 124. The first threshold distance is at least one of (i) between about 0.01×exhaust_radius to about 1.5×exhaust_radius, (ii) between about 0.01×exhaust_radius to about 1×exhaust_radius, or (iii) between about 0.01×exhaust_radius to about 0.5×exhaust_radius, wherein exhaust_radius corresponds to a first exhaust port radius 222 associated with the exhaust port 124. Other values of the first threshold distance are within the scope of the present disclosure.

In some embodiments, the first oval-shaped opening 140 is oriented such that the first major axis 202 of the first oval-shaped opening 140 intersects at least one of a point on the first pedestal base 122, a center point 212 associated with the first pedestal base 122 or a point (e.g., a point on the first pedestal base 122) that is within a second threshold distance of the center point 212 associated with the first pedestal base 122. The second threshold distance is at least one of (i) between about 0.01×base_radius to about 1.5×base _radius, (ii) between about 0.01×base_radius to about 1×base_radius, or (iii) between about 0.01×base_radius to about 0.5×base_radius, wherein base_radius corresponds to a first pedestal base radius 224 associated with the first pedestal base 122. Other values of the second threshold distance are within the scope of the present disclosure.

In some embodiments, a first line 204 intersects with the first major axis 202 of the first oval-shaped opening 140 at a first angle 206. The first angle 206 is at least one of (i) between about 80 degrees to about 100 degrees, (ii) between about 85 degrees to about 95 degrees, or (iii) about 90 degrees. Other values of the first angle 206 are within the scope of the present disclosure. In some embodiments, the first line 204 intersects with the center point 212 associated with the first pedestal base 122. In some embodiments, the first line 204 defines a first region r1 of the first oval-shaped opening 140 and a second region r2 of the first oval-shaped opening 140. In some embodiments, the first region r1 corresponds to a region, of the first oval-shaped opening 140, that is on a first side of the first line 204 and is laterally offset from the first pedestal base 122. In some embodiments, the second region r2 corresponds to a region, of the first oval-shaped opening 140, that is on a second side of the first line 204 and is laterally offset from the first pedestal base 122.

FIG. 2B illustrates a top view of the first exhaust baffle 126 showing the first region r1 with a first pattern and the second region r2 with a second pattern, in accordance with some embodiments. In some embodiments, the first oval-shaped opening 140 is defined by one or more first exhaust baffle walls of the first exhaust baffle 126. In some embodiments, the one or more first exhaust baffle walls comprise a first exhaust baffle wall comprising a first exhaust baffle wall portion 232a on the first side of the first line 204 and a second exhaust baffle wall portion 232b on the second side of the first line 204. To distinguish between the first exhaust baffle wall portion 232a and the second exhaust baffle wall portion 232b in FIG. 2B, the first exhaust baffle wall portion 232a is depicted with a greater boundary thickness than the second exhaust baffle wall portion 232b, in accordance with some embodiments. In some embodiments, the first region r1 is between the first exhaust baffle wall portion 232a and the first pedestal base 122. In some embodiments, the second region r2 is between the second exhaust baffle wall portion 232b and the first pedestal base 122. In some embodiments, the first region r1 corresponds to a region, on the first side of the first line 204, through which the first process gas flows (e.g., the first process gas flows in a downwards manner through the first region r1 without being obstructed and/or blocked by at least one of the first exhaust baffle 126 or the first pedestal base 122). In some embodiments, the second region r2 corresponds to a region, on the second side of the first line 204, in which the first process gas flows (e.g., the second process gas flows in a downwards manner through the second region r2 without being obstructed and/or blocked by at least one of the first exhaust baffle 126 or the first pedestal base 122).

In some embodiments, an area A2 of the second region r2 is greater than an area A1 of the first region r1. In some embodiments, the area A2 is between about 2×A1 to about 10×A1. In some embodiments, implementing the apparatus 100 such that the area A2 of the second region r2 is greater than the area A1 of the first region r1 (and/or such that the area A2 is between about 2×A1 to about 10×A1) provides for increased uniformity of distribution of the first process gas across the first semiconductor wafer 108, such as where different portions of the first semiconductor wafer 108 are exposed to similar amounts of the first process gas during the first semiconductor fabrication process, such as due, at least in part, to the second region r2 being farther from the exhaust port 124 than the first region r1. In some embodiments, implementing the apparatus 100 such that the area A2 of the second region r2 is greater than the area A1 of the first region r1 (and/or such that the area A2 is between about 2×A1 to about 10×A1) provides for increased uniformity of etch rates across the first semiconductor wafer 108.

FIG. 2C illustrates a top view of the first exhaust baffle 126 and the first oval-shaped opening 140 of the first exhaust baffle 126 relative to the first pedestal base 122 annotated with various dimensions, in accordance with some embodiments, in accordance with some embodiments. Dimension A corresponds to a distance between the first vertex v1 of the first oval-shaped opening 140 and a point 262 on an edge of the first exhaust baffle 126. In some embodiments, the edge of the first exhaust baffle 126 corresponds to an outer circumference of the first exhaust baffle 126. In some embodiments, the edge of the first exhaust baffle 126 is aligned with and/or in contact with an inner surface of a chamber wall (e.g., the first peripheral wall 151) defining the first processing chamber 132. In some embodiments, the center point 212 associated with the first pedestal base 122 is about equal to (and/or is within a threshold distance of) a center point associated with at least one of the chamber wall (e.g., the first peripheral wall 151) or the first processing chamber 132. In some embodiments, the center point 212 associated with the first pedestal base 122 is about equal to (and/or is within a threshold distance of) a center point associated with the first exhaust baffle 126. In some embodiments, a first distance between the first vertex v1 and at least one of the center point 212 associated with the first pedestal base 122, the center point associated with at least one of the chamber wall or the first processing chamber 132, or the center point associated with the first exhaust baffle 126 is different than a second distance between the second vertex v2 and at least one of the center point 212 associated with the first pedestal base 122, the center point associated with at least one of the chamber wall or the first processing chamber 132, or the center point associated with the first exhaust baffle 126. In some embodiments, the second distance is greater than the first distance.

Dimension A′ corresponds to a distance between the first vertex v1 and a point 252 on an edge of the first pedestal base 122. In some embodiments, the first major axis 202 of the first oval-shaped opening 140 intersects at least one of the point 262 or the point 252. Dimension B corresponds to a distance between a point 282 on the second exhaust baffle wall defining the first oval-shaped opening 140 and a point 264 on the edge of the first exhaust baffle 126. Dimension B′ corresponds to a distance between the point 282 on the second exhaust baffle wall and a point 254 on the edge of the first pedestal base 122. In some embodiments, the first line 204 intersects at least one of the point 264, the point 282, or the point 254. Dimension C corresponds to a distance between a point 284 on the second exhaust baffle wall defining the first oval-shaped opening 140 and a point 266 on the edge of the first exhaust baffle 126. Dimension C′ corresponds to a distance between the point 284 on the second exhaust baffle wall and a point 256 on the edge of the first pedestal base 122. In some embodiments, the first line 204 intersects at least one of the point 266, the point 284, or the point 256. Dimension D corresponds to a distance between the second vertex v2 of the first oval-shaped opening 140 and a point 268 on an edge of the first exhaust baffle 126. Dimension D′ corresponds to a distance between the second vertex v2 and a point 258 on an edge of the first pedestal base 122. In some embodiments, the first major axis 202 of the first oval-shaped opening 140 intersects at least one of the point 268 or the point 258.

In some embodiments, the Dimension D′ is between about 1×A′ to about 10×A′. In some embodiments, the Dimension C′ is between about 0.5×A′ to about 3×A′. In some embodiments, the Dimension B′ is between about 0.5×A′ to about 3×A′. In some embodiments, the Dimension B′ is about equal to the Dimension C′. In some embodiments, the Dimension A is between about 1×A′ to about 10×A′. In some embodiments, the Dimension B is between about 1×B′ to about 10×B′. In some embodiments, the Dimension C is between about 1×C′ to about 10×C′. In some embodiments, the Dimension D′ is between about 1×D to about 10×D. In some embodiments, implementing the apparatus 100 to achieve one, some or all of the relationships between dimensions provided herein provides for at least one of (i) increased uniformity of distribution of the first process gas across the first semiconductor wafer 108, such as where different portions of the first semiconductor wafer 108 are exposed to similar amounts of the first process gas during the first semiconductor fabrication process, or (ii) increased uniformity of etch rates across the first semiconductor wafer 108.

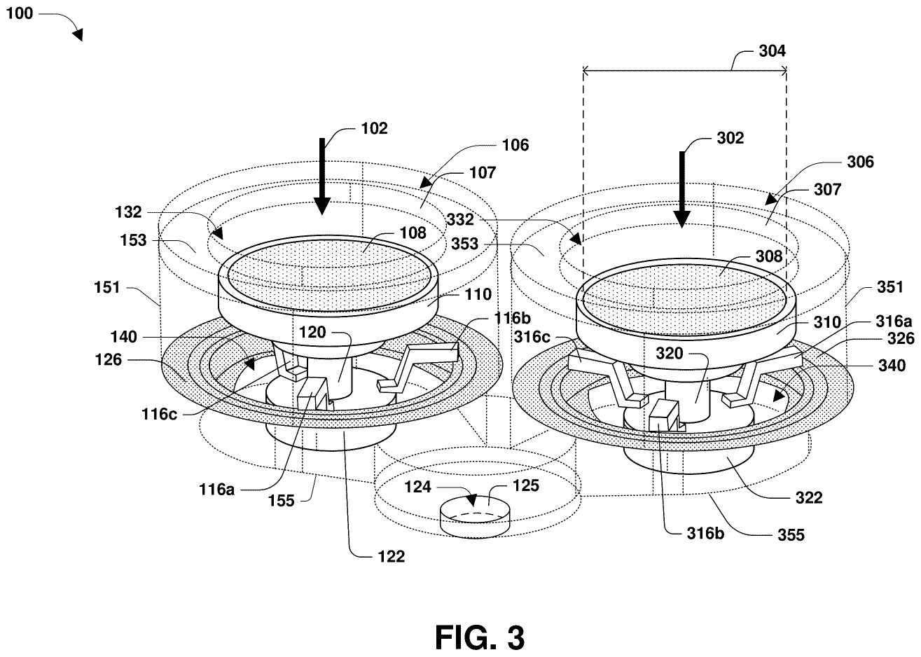

In some embodiments, the apparatus 100 includes a plurality of processing chambers. FIG. 3 illustrates a perspective view of the apparatus 100 in accordance with some embodiments. In some embodiments, the apparatus 100 comprises at least one of a second ceiling 353, a second floor 355, or one or more second chamber walls, such as a second peripheral wall 351, to define a second processing chamber 332. In some embodiments, at least one of (i) the second floor 355 is annular, (ii) the second ceiling 353 is annular, or (iii) the second peripheral wall 351 is cylindrical such that at least some of the second processing chamber 332 is a cylindrical volume. For clarity, some of the apparatus 100 (e.g., the second ceiling 353, the second floor 355, one or more chamber walls, one or more other parts of a body of the apparatus 100, etc.) are depicted transparently with dotted-line boundaries in FIG. 3.

In some embodiments, the apparatus 100 comprises a second wafer support structure 310 configured to support a second semiconductor wafer 308 in the second processing chamber 332. A diameter 304 of the second semiconductor wafer 308 is at least one of (i) between about 10 millimeters to about 3,000 millimeters, (ii) between about 100 millimeters to about 500 millimeters, or (iii) between about 250 millimeters to about 350 millimeters. Other values of the diameter 304 are within the scope of the present disclosure. In some embodiments, the second semiconductor wafer 308 is subjected to a second semiconductor fabrication process while the second semiconductor wafer 308 is supported by the second wafer support structure 310. In some embodiments, the second wafer support structure 310 comprises at least one of a pedestal, a platform, a chuck, etc. that at least one of (i) supports the second semiconductor wafer 308 via ESC, (ii) supports the second semiconductor wafer 308 via mechanical clamping, or (iii) supports the second semiconductor wafer 308 using one or more other suitable techniques. In some embodiments, the second semiconductor wafer 308 comprises at least one of a substrate, a photomask, a semiconductor device, a die, etc.

In some embodiments, the second semiconductor fabrication process comprises exposing the second semiconductor wafer 308, such as a surface of the second semiconductor wafer 308, to a second process gas. The second semiconductor fabrication process comprises an etching process. The semiconductor processing station comprises etching equipment, such as at least one of plasma etching equipment, wet etching equipment, dry etching equipment, RIE equipment, ALE equipment, or buffered oxide etching equipment. The second process gas comprises a second etching gas comprising at least one of methane (CH4), hydrogen (H2), helium (He), plasma, one or more etching chemicals, or one or more other suitable gases and/or chemicals. Other types of semiconductor fabrication processes, semiconductor processing stations and/or process gases are within the scope of the present disclosure. In some embodiments, the apparatus 100 comprises a second pedestal base 322 configured to support the second wafer support structure 310. In some embodiments, the second pedestal base 322 provides foundational support to the second wafer support structure 310. In some embodiments, a second object 320, such as a cylinder, extends between the second pedestal base 322 and the second wafer support structure 310. In some embodiments, at least one of a first side (e.g., bottom side) of the second object 320 is attached to the second pedestal base 322 or a second side (e.g., top side) is attached to the second wafer support structure 310. In some embodiments, the second semiconductor wafer 308 comprises a gate-all-around (GAA) transistor architecture. In some embodiments, the second semiconductor fabrication process comprises a stage (e.g., etching stage) of fabrication of a semiconductor device comprising one or more transistors having gate-all-around architecture.

In some embodiments, the apparatus 100 comprises a second gas inlet port 306. In some embodiments, the second gas inlet port 306 is defined by one or more second inlet port walls of the apparatus 100, such as a second gas inlet port wall 307. In some embodiments, the second gas inlet port 306 is configured to conduct the second process gas into the second processing chamber 332. In some embodiments, the apparatus 100 comprises a second showerhead (e.g., a mars showerhead) that introduces the second process gas into the second processing chamber 332 via the second gas inlet port 306 defined by the second showerhead and one or more other apertures (not shown) defined by the second showerhead (e.g., the second gas inlet port 306 corresponds to an aperture of a plurality of apertures defined by the second showerhead to introduce the second process gas into the second processing chamber 332).

In some embodiments, the second process gas is conducted from a second gas source (not shown) through the second gas inlet port 306 into the second processing chamber 332. In some embodiments, the second process gas is stored in a second cylinder (not shown) of the second gas source. In some embodiments, the second gas source is fluidly coupled to the second gas inlet port 306 and/or the second processing chamber 332 through a second control valve (not shown). In some embodiments, the second control valve regulates the flow of the second process gas from the second cylinder into the second processing chamber 332. In some embodiments, the second gas inlet port 306 conducts at least some of the second process gas in a direction 302 (e.g., downwards direction) into the second processing chamber 332.

In some embodiments, the apparatus 100 comprises an exhaust port 124. In some embodiments, the exhaust port 124 is defined by one or more exhaust port walls of the apparatus 100, such as exhaust port wall 125. In some embodiments, the second process gas is removed from the second processing chamber 332 through the exhaust port 124.

In some embodiments, the vacuum source 111 (not shown in FIG. 3) exposes the second processing chamber 332 to a vacuum (e.g., partial vacuum). In some embodiments, the vacuum (e.g., the partial vacuum) is at a lower pressure than a pressure within the second processing chamber 332 such that at least a portion of the second process gas flows along a flow path from the second processing chamber 332 to the vacuum source 111 through the exhaust port 124. In some embodiments, the adaptive pressure controller 112 regulates a pressure to which the second processing chamber 332 is exposed via the vacuum pump 114.

In some embodiments, the apparatus 100 comprises a second exhaust baffle 326. In some embodiments, the second exhaust baffle 326 is between the second pedestal base 322 and the second wafer support structure 310. In some embodiments, the second exhaust baffle 326 has a second oval-shaped opening 340. In some embodiments, the second object 320 extends through the second oval-shaped opening 340 between the second pedestal base 322 and the second wafer support structure 310. In some embodiments, a second flow path, along which the second process gas flows as the second process gas is removed from the second processing chamber 332, passes through the second oval-shaped opening 340 of the second exhaust baffle 326. In some embodiments, the second exhaust baffle 326 is at least partially sealed against the second peripheral wall 351 (and/or other wall defining the second processing chamber 332) such that most or all of gas that flows from a first part of the second processing chamber 332 over the second exhaust baffle 326 to a second part of the second processing chamber 332 under the second exhaust baffle 326 is conducted through the second oval-shaped opening 340 (e.g., none of the gas or less than a threshold amount of the gas is conducted from over the second exhaust baffle 326 to under the second exhaust baffle 326 through an unsealed gap between an edge of the second exhaust baffle 326 and the second peripheral wall 351).

In some embodiments, the second exhaust baffle 326 having the second oval-shaped opening 340 provides for increased uniformity of distribution of the second process gas across the second semiconductor wafer 308, such as where different portions of the second semiconductor wafer 308 are exposed to similar and/or more uniform amounts of the second process gas during the second semiconductor fabrication process. In some embodiments, the increased uniformity associated with the second process gas (e.g., the etching gas) provides improved processing uniformity (e.g., etching uniformity of etching rates) of the second semiconductor fabrication process (e.g., etching process). In some embodiments, a third flow rate of a first portion of the second process gas over a first portion of the second semiconductor wafer 308 is equal or about equal to a fourth flow rate of a second portion of the second process gas over a second portion of the second semiconductor wafer 308 due to the second exhaust baffle 326 having the second oval-shaped opening 340. In some embodiments, the first portion of the second semiconductor wafer 308 is proximal an edge of the second semiconductor wafer 308 and distal a center of the second semiconductor wafer 308. In some embodiments, the second portion of the second semiconductor wafer 308 is proximal the center of the second semiconductor wafer 308 and distal the edge of the second semiconductor wafer 308. In some embodiments, a difference between the third flow rate and the fourth flow rate is reduced due to the second exhaust baffle 326 having the second oval-shaped opening 340. In some embodiments, a third etch rate of the first portion of the second semiconductor wafer 308 is equal or about equal to a fourth etch rate of the second portion of the second semiconductor wafer 308, such as due, at least in part, to the second exhaust baffle 326 having the second oval-shaped opening 340. In some embodiments, a difference between the third etch rate and the fourth etch rate is reduced due, at least in part, to the second exhaust baffle 326 having the second oval-shaped opening 340.

In some embodiments, the exhaust port 124 is laterally offset from at least one of the second semiconductor wafer 308, the second wafer support structure 310, the second exhaust baffle 326, the second object 320, or the second pedestal base 322. In some embodiments, the second gas inlet port 306 overlies at least one of the second semiconductor wafer 308, the second wafer support structure 310, the second exhaust baffle 326, the second object 320, or the second pedestal base 322. In some embodiments, the second semiconductor wafer 308 overlies at least one of the second wafer support structure 310, the second exhaust baffle 326, the second object 320, or the second pedestal base 322. In some embodiments, the second wafer support structure 310 overlies at least one of the second exhaust baffle 326, the second object 320, or the second pedestal base 322. In some embodiments, at least one of the second object 320 or the second exhaust baffle 326 overlies the second pedestal base 322. In some embodiments, the second oval-shaped opening 340 defined by the second exhaust baffle 326 overlies the second pedestal base 322.

In some embodiments, the apparatus 100 comprises a second set of pin holders (e.g., a set of one or more pin holders). Although FIG. 3 shows three pin holders of the second set of pin holders, other numbers of pin holders of the second set of pin holders other than three are within the scope of the present disclosure. In some embodiments, the second set of pin holders comprises at least one of a fourth pin holder 316a, a fifth pin holder 316b, a sixth pin holder 316c, or one or more other pin holders.

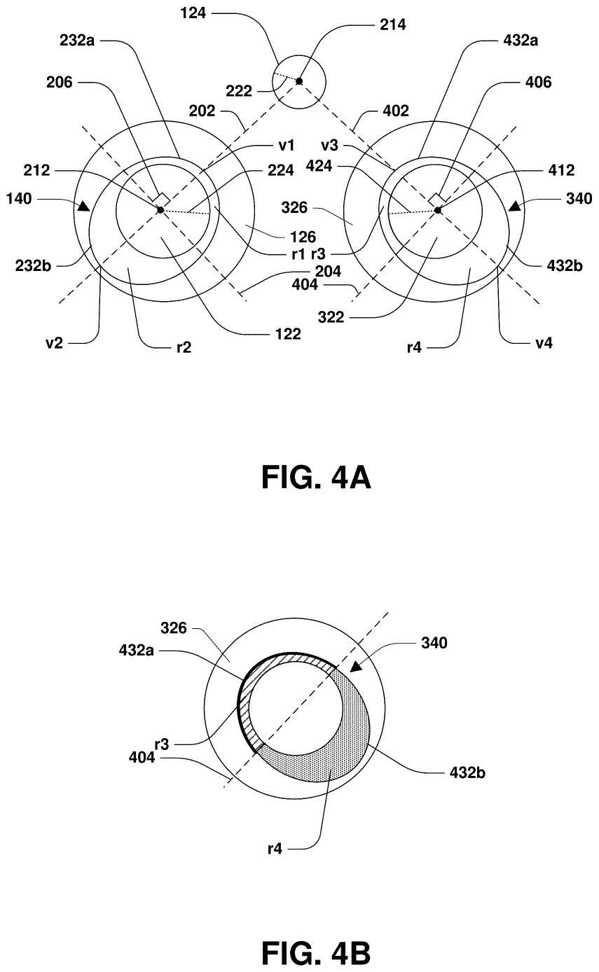

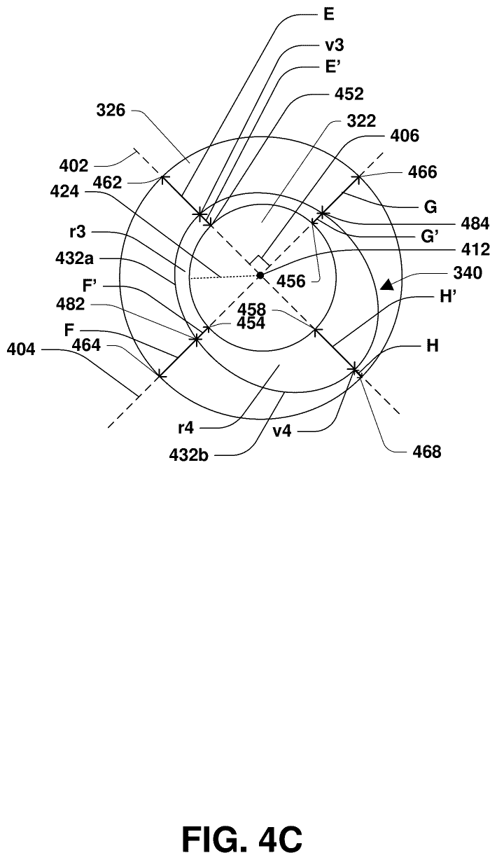

In some embodiments, an orientation of the second oval-shaped opening 340 defined by the second exhaust baffle 326 is configured based upon an orientation of the exhaust port 124 relative to the second exhaust baffle 326 to provide for increased uniformity of distribution of the second process gas across the second semiconductor wafer 308. In some embodiments, the second oval-shaped opening 340 is oriented using one or more of the techniques provided herein with respect to FIGS. 4A-4C.

FIG. 4A illustrates a top view of the first exhaust baffle 126, the first pedestal base 122, the second exhaust baffle 326, the second pedestal base 322, and the exhaust port 124 in accordance with some embodiments. In some embodiments, the second oval-shaped opening 340 has a third vertex v3 and a fourth vertex v4. The third vertex v3 is associated with a third curvature. The fourth vertex v4 is associated with a fourth curvature. In some embodiments, the third curvature is different than the fourth curvature such that the second oval-shaped opening 340 has a more rounded and/bulbous end and a more narrow and/or tapered end. In some embodiments, the fourth curvature is greater than the third curvature (e.g., the third vertex v3 corresponds to the more rounded and/bulbous end of the second oval-shaped opening 340 and the fourth vertex v4 corresponds to the more narrow and/or tapered end of the second oval-shaped opening 340). Although FIG. 4A illustrates an embodiment in which the third curvature is different than the fourth curvature, embodiments are contemplated in which at least one of (i) the third curvature is about equal to the fourth curvature, (ii) the second oval-shaped opening 340 has an elliptical shape, or (iii) the second oval-shaped opening 340 is symmetrical and/or substantially symmetrical about two axes (e.g., major axis and minor axis).

In some embodiments, a second major axis 402 of the second oval-shaped opening 340 intersects with the third vertex v3 and the fourth vertex v4. In some embodiments, the second oval-shaped opening 340 is oriented such that the second major axis 402 of the second oval-shaped opening 340 intersects at least one of a point on the exhaust port 124, the center point 214 associated with the exhaust port 124 or a point (e.g., a point on the exhaust port 124) that is within a third threshold distance of the center point 214 associated with the exhaust port 124. The third threshold distance is at least one of (i) between about 0.01×exhaust_radius to about 1.5×exhaust_radius, (ii) between about 0.01×exhaust_radius to about 1×exhaust_radius, or (iii) between about 0.01×exhaust_radius to about 0.5×exhaust_radius, wherein exhaust_radius corresponds to the first exhaust port radius 222 associated with the exhaust port 124. Other values of the third threshold distance are within the scope of the present disclosure.

In some embodiments, the second oval-shaped opening 340 is oriented such that the second major axis 402 of the second oval-shaped opening 340 intersects at least one of a point on the second pedestal base 322, a center point 412 associated with the second pedestal base 322 or a point (e.g., a point on the second pedestal base 322) that is within a fourth threshold distance of the center point 412 associated with the second pedestal base 322. The fourth threshold distance is at least one of (i) between about 0.01×base_radius to about 1.5×base _radius_2, (ii) between about 0.01×base_radius_2 to about 1×base_radius_2, or (iii) between about 0.01×base_radius_2 to about 0.5×base_radius_2, wherein base_radius_2 corresponds to a second pedestal base radius 424 associated with the second pedestal base 322. Other values of the fourth threshold distance are within the scope of the present disclosure.

In some embodiments, a second line 404 intersects with the second major axis 402 of the second oval-shaped opening 340 at a second angle 406. The second angle 406 is at least one of (i) between about 80 degrees to about 100 degrees, (ii) between about 85 degrees to about 95 degrees, or (iii) about 90 degrees. Other values of the second angle 406 are within the scope of the present disclosure. In some embodiments, the second line 404 intersects with the center point 412 associated with the second pedestal base 322. In some embodiments, the second line 404 defines a third region r3 of the second oval-shaped opening 340 and a fourth region r4 of the second oval-shaped opening 340. In some embodiments, the third region r3 corresponds to a region, of the second oval-shaped opening 340, that is on a first side of the second line 404 and is laterally offset from the second pedestal base 322. In some embodiments, the fourth region r4 corresponds to a region, of the second oval-shaped opening 340, that is on a second side of the second line 404 and is laterally offset from the second pedestal base 322.

FIG. 4B illustrates a top view of the second exhaust baffle 326 showing the third region r3 with the first pattern and the fourth region r4 with the second pattern, in accordance with some embodiments. In some embodiments, the second oval-shaped opening 340 is defined by one or more second exhaust baffle walls of the second exhaust baffle 326. In some embodiments, the one or more second exhaust baffle walls comprise a second exhaust baffle wall comprising a third exhaust baffle wall portion 432a on the first side of the second line 404 and a fourth exhaust baffle wall portion 432b on the second side of the second line 404. To distinguish between the third exhaust baffle wall portion 432a and the fourth exhaust baffle wall portion 432b in FIG. 4B, the third exhaust baffle wall portion 432a is depicted with a greater boundary thickness than the fourth exhaust baffle wall portion 432b, in accordance with some embodiments. In some embodiments, the third region r3 is between the third exhaust baffle wall portion 432a and the second pedestal base 322. In some embodiments, the fourth region r4 is between the fourth exhaust baffle wall portion 432b and the second pedestal base 322. In some embodiments, the third region r3 corresponds to a region, on the first side of the second line 404, through which the second process gas flows (e.g., the second process gas flows in a downwards manner through the third region r3 without being obstructed and/or blocked by at least one of the second exhaust baffle 326 or the second pedestal base 322). In some embodiments, the fourth region r4 corresponds to a region, on the second side of the second line 404, in which the second process gas flows (e.g., the second process gas flows in a downwards manner through the fourth region r4 without being obstructed and/or blocked by at least one of the second exhaust baffle 326 or the second pedestal base 322).

In some embodiments, an area A4 of the fourth region r4 is greater than an area A3 of the third region r3. In some embodiments, the area A4 is between about 2×A3 to about 10×A3. In some embodiments, implementing the apparatus 100 such that the area A4 of the fourth region r4 is greater than the area A3 of the third region r3 (and/or such that the area A4 is between about 2×A3 to about 10×A3) provides for increased uniformity of distribution of the second process gas across the second semiconductor wafer 308, such as where different portions of the second semiconductor wafer 308 are exposed to similar amounts of the second process gas during the second semiconductor fabrication process, such as due, at least in part, to the fourth region r4 being farther from the exhaust port 124 than the third region r3. In some embodiments, implementing the apparatus 100 such that the area A4 of the fourth region r4 is greater than the area A3 of the third region r3 (and/or such that the area A4 is between about 2×A3 to about 10×A3) provides for increased uniformity of etch rates across the second semiconductor wafer 308.

FIG. 4C illustrates a top view of the second exhaust baffle 326 and the second oval-shaped opening 340 of the second exhaust baffle 326 relative to the second pedestal base 322 annotated with various dimensions, in accordance with some embodiments, in accordance with some embodiments. Dimension E corresponds to a distance between the third vertex v3 of the second oval-shaped opening 340 and a point 462 on an edge of the second exhaust baffle 326. In some embodiments, the edge of the second exhaust baffle 326 corresponds to an outer circumference of the second exhaust baffle 326. In some embodiments, the edge of the second exhaust baffle 326 is aligned with and/or in contact with an inner surface of a chamber wall (e.g., the second peripheral wall 351) defining the second processing chamber 332. In some embodiments, the center point 412 associated with the second pedestal base 322 is about equal to (and/or is within a threshold distance of) a center point associated with at least one of the chamber wall (e.g., the second peripheral wall 351) or the second processing chamber 332. In some embodiments, the center point 412 associated with the second pedestal base 322 is about equal to (and/or is within a threshold distance of) a center point associated with the second exhaust baffle 326. In some embodiments, a third distance between the third vertex v3 and at least one of the center point 412 associated with the second pedestal base 322, the center point associated with at least one of the chamber wall or the second processing chamber 332, or the center point associated with the second exhaust baffle 326 is different than a second distance between the fourth vertex v2 and at least one of the center point 412 associated with the second pedestal base 322, the center point associated with at least one of the chamber wall or the second processing chamber 332, or the center point associated with the second exhaust baffle 326. In some embodiments, the fourth distance is greater than the third distance.

Dimension E′ corresponds to a distance between the third vertex v3 and a point 452 on an edge of the second pedestal base 322. In some embodiments, the second major axis 402 of the second oval-shaped opening 340 intersects at least one of the point 462 or the point 452. Dimension F corresponds to a distance between a point 482 on the second exhaust baffle wall defining the second oval-shaped opening 340 and a point 464 on the edge of the second exhaust baffle 326. Dimension F′ corresponds to a distance between the point 482 on the second exhaust baffle wall and a point 454 on the edge of the second pedestal base 322. In some embodiments, the second line 404 intersects at least one of the point 464, the point 482, or the point 454. Dimension G corresponds to a distance between a point 484 on the second exhaust baffle wall defining the second oval-shaped opening 340 and a point 466 on the edge of the second exhaust baffle 326. Dimension G′ corresponds to a distance between the point 484 on the second exhaust baffle wall and a point 456 on the edge of the second pedestal base 322. In some embodiments, the second line 404 intersects at least one of the point 466, the point 484, or the point 456. Dimension H corresponds to a distance between the fourth vertex v4 of the second oval-shaped opening 340 and a point 468 on an edge of the second exhaust baffle 326. Dimension H′ corresponds to a distance between the fourth vertex v4 and a point 458 on an edge of the second pedestal base 322. In some embodiments, the second major axis 402 of the second oval-shaped opening 340 intersects at least one of the point 468 or the point 458.

In some embodiments, the Dimension H′ is between about 1×E′ to about 10×E′. In some embodiments, the Dimension G′ is between about 0.5×E′ to about 3×E′. In some embodiments, the Dimension F′ is between about 0.5×E′ to about 3×E′. In some embodiments, the Dimension F′ is about equal to the Dimension G′. In some embodiments, the Dimension E is between about 1×E′ to about 10×E′. In some embodiments, the Dimension F is between about 1×F′ to about 10×F′. In some embodiments, the Dimension G is between about 1×G′ to about 10×G′. In some embodiments, the Dimension H′ is between about 1×H to about 10×H. In some embodiments, implementing the apparatus 100 to achieve one, some or all of the relationships between dimensions provided herein provides for at least one of (i) increased uniformity of distribution of the second process gas across the second semiconductor wafer 308, such as where different portions of the second semiconductor wafer 308 are exposed to similar amounts of the second process gas during the second semiconductor fabrication process, or (ii) increased uniformity of etch rates across the second semiconductor wafer 308.

In some embodiments, the first semiconductor fabrication process and the second semiconductor fabrication process are performed concurrently. In some embodiments, the first semiconductor fabrication process and the second semiconductor fabrication process are performed at different times.

In some embodiments, an apparatus is provided. The apparatus includes a wafer support structure configured to support a semiconductor wafer in a processing chamber defined by one or more chamber walls. The apparatus includes a gas inlet port defined by one or more inlet port walls configured to conduct a process gas into the processing chamber such that the semiconductor wafer is exposed to the process gas. The apparatus includes an exhaust port defined by one or more exhaust port walls through which the process gas is removed from the processing chamber. The apparatus includes an exhaust baffle having an oval-shaped opening defined by one or more exhaust baffle walls. A flow path, along which the process gas flows as the process gas is removed from the processing chamber, passes through the oval-shaped opening.

In some embodiments, an apparatus is provided. The apparatus includes a first wafer support structure configured to support a first semiconductor wafer in a first processing chamber defined by one or more first chamber walls. The apparatus includes a first gas inlet port defined by one or more first inlet port walls configured to conduct a first process gas into the first processing chamber such that the first semiconductor wafer is exposed to the first process gas. The apparatus includes a second wafer support structure configured to support a second semiconductor wafer in a second processing chamber defined by one or more second chamber walls. The apparatus includes a second gas inlet port defined by one or more second inlet port walls configured to conduct a second process gas into the second processing chamber such that the second semiconductor wafer is exposed to the second process gas. The apparatus includes an exhaust port defined by one or more exhaust port walls through which the first process gas is removed from the first processing chamber and the second process gas is removed from the second processing chamber. The apparatus includes a first exhaust baffle having a first oval-shaped opening defined by one or more first exhaust baffle walls. A first flow path, along which the first process gas flows as the first process gas is removed from the first processing chamber, passes through the first oval-shaped opening. The apparatus includes a second exhaust baffle having a second oval-shaped opening defined by one or more second exhaust baffle walls. A second flow path, along which the second process gas flows as the second process gas is removed from the second processing chamber, passes through the second oval-shaped opening.

In some embodiments, an apparatus is provided. The apparatus includes one or more chamber walls defining a processing chamber. The apparatus includes a gas inlet port defined by one or more inlet port walls configured to conduct a process gas into the processing chamber. The apparatus includes an exhaust port defined by one or more exhaust port walls through which the process gas is removed from the processing chamber. The apparatus includes an exhaust baffle having an oval-shaped opening defined by one or more exhaust baffle walls. A flow path, along which the process gas flows as the process gas is removed from the processing chamber, passes through the oval-shaped opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that Yeah illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally to be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. An apparatus, comprising:
a wafer support structure configured to support a semiconductor wafer in a processing chamber defined by one or more chamber walls;
a gas inlet port defined by one or more inlet port walls configured to conduct a process gas into the processing chamber such that the semiconductor wafer is exposed to the process gas;
an exhaust port defined by one or more exhaust port walls through which the process gas is removed from the processing chamber; and
an exhaust baffle having an oval-shaped opening defined by one or more exhaust baffle walls, wherein a flow path, along which the process gas flows as the process gas is removed from the processing chamber, passes through the oval-shaped opening.

2. The apparatus of claim 1, wherein:
a major axis of the oval-shaped opening intersects at least one of a point on the exhaust port, a center point associated with the exhaust port, or a point within a threshold distance of the center point associated with the exhaust port.

3. The apparatus of claim 1, comprising:
a pedestal base configured to support the wafer support structure, wherein the oval-shaped opening overlies the pedestal base.

4. The apparatus of claim 1, wherein:
a first vertex of the oval-shaped opening is a first distance from a center point associated with the exhaust port and a second vertex of the oval-shaped opening is a second distance, different than the first distance, from the center point associated with the exhaust port.

5. The apparatus of claim 4, wherein:
the first vertex is associated with a first curvature; and
the second vertex is associated with a second curvature greater than the first curvature.

6. The apparatus of claim 4, comprising:
a pedestal base configured to support the wafer support structure, wherein:
the first vertex is a third distance from a center point associated with the pedestal base and the second vertex is a fourth distance, different than the third distance, from the center point associated with the pedestal base.

7. The apparatus of claim 1, comprising:
a pedestal base configured to support the wafer support structure, wherein:
a major axis of the oval-shaped opening intersects at least one of a point on the pedestal base, a center point associated with the pedestal base, or a point within a threshold distance of the center point associated with the pedestal base.

8. The apparatus of claim 1, wherein:
the exhaust port is configured to be fluidly coupled to a vacuum source to generate a vacuum that establishes a flow of the process gas over the semiconductor wafer supported by the wafer support structure.

9. An apparatus, comprising:
a first wafer support structure configured to support a first semiconductor wafer in a first processing chamber defined by one or more first chamber walls;
a first gas inlet port defined by one or more first inlet port walls configured to conduct a first process gas into the first processing chamber such that the first semiconductor wafer is exposed to the first process gas;
a second wafer support structure configured to support a second semiconductor wafer in a second processing chamber defined by one or more second chamber walls;
a second gas inlet port defined by one or more second inlet port walls configured to conduct a second process gas into the second processing chamber such that the second semiconductor wafer is exposed to the second process gas;
an exhaust port defined by one or more exhaust port walls through which the first process gas is removed from the first processing chamber and the second process gas is removed from the second processing chamber;
a first exhaust baffle having a first oval-shaped opening defined by one or more first exhaust baffle walls, wherein a first flow path, along which the first process gas flows as the first process gas is removed from the first processing chamber, passes through the first oval-shaped opening; and
a second exhaust baffle having a second oval-shaped opening defined by one or more second exhaust baffle walls, wherein a second flow path, along which the second process gas flows as the second process gas is removed from the second processing chamber, passes through the second oval-shaped opening.

10. The apparatus of claim 9, wherein at least one of:
a first major axis of the first oval-shaped opening intersects at least one of a point on the exhaust port, a center point associated with the exhaust port, or a point within a threshold distance of the center point associated with the exhaust port; or
a second major axis of the second oval-shaped opening intersects at least one of the point on the exhaust port, the center point associated with the exhaust port, or the point within the threshold distance of the center point associated with the exhaust port.

11. The apparatus of claim 9, comprising at least one of:
a first pedestal base configured to support the first wafer support structure, wherein the first oval-shaped opening overlies the first pedestal base; or
a second pedestal base configured to support the second wafer support structure, wherein the second oval-shaped opening overlies the second pedestal base.

12. The apparatus of claim 9, wherein at least one of:
a first vertex of the first oval-shaped opening is a first distance from a center point associated with the exhaust port and a second vertex of the first oval-shaped opening is a second distance, different than the first distance, from the center point associated with the exhaust port; or
a first vertex of the second oval-shaped opening is a third distance from the center point associated with the exhaust port and a second vertex of the second oval-shaped opening is a fourth distance, different than the third distance, from the center point associated with the exhaust port.

13. The apparatus of claim 12, wherein:
the first vertex of the first oval-shaped opening is associated with a first curvature; and
the second vertex of the first oval-shaped opening is associated with a second curvature greater than the first curvature.

14. The apparatus of claim 13, wherein:
the first vertex of the second oval-shaped opening is associated with a third curvature; and
the second vertex of the second oval-shaped opening is associated with a fourth curvature greater than the third curvature.

15. The apparatus of claim 14, comprising:
a first pedestal base configured to support the first wafer support structure, wherein:
the first vertex of the first oval-shaped opening is a fifth distance from a center point associated with the first pedestal base and the second vertex of the first oval-shaped opening is a sixth distance, different than the fifth distance, from the center point associated with the first pedestal base.

16. The apparatus of claim 15, comprising:
a second pedestal base configured to support the second wafer support structure, wherein:
the first vertex of the second oval-shaped opening is a seventh distance from a center point associated with the second pedestal base and the second vertex of the second oval-shaped opening is an eighth distance, different than the seventh distance, from the center point associated with the second pedestal base.

17. The apparatus of claim 9, wherein:
the exhaust port is configured to be fluidly coupled to a vacuum source to generate a vacuum that establishes at least one of:
a first flow of the first process gas over the first semiconductor wafer supported by the first wafer support structure; or
a second flow of the second process gas over the second semiconductor wafer supported by the second wafer support structure.

18. An apparatus, comprising:
one or more chamber walls defining a processing chamber;
a gas inlet port defined by one or more inlet port walls configured to conduct a process gas into the processing chamber;
an exhaust port defined by one or more exhaust port walls through which the process gas is removed from the processing chamber; and
an exhaust baffle having an oval-shaped opening defined by one or more exhaust baffle walls, wherein a flow path, along which the process gas flows as the process gas is removed from the processing chamber, passes through the oval-shaped opening.

19. The apparatus of claim 18, wherein:
a major axis of the oval-shaped opening intersects at least one of a point on the exhaust port, a center point associated with the exhaust port, or a point within a threshold distance of the center point associated with the exhaust port.

20. The apparatus of claim 18, wherein:
a first vertex of the oval-shaped opening is a first distance from a point on the exhaust port and a second vertex of the oval-shaped opening is a second distance, different than the first distance, from the point on the exhaust port.
